(19) United States
(12) Patent Application Publication
(10) Pub. No.: US 2026/0336038 A1
(43) Pub. Date: Oct. 29, 2026

(54) BONDING COMPOSITION FOR LOW-TEMPERATURE SINTERING

(71) Applicant: DAE JOO ELECTRONIC MATERIALS CO., LTD., Siheung-si, Gyeonggi-do (KR)

(72) Inventors: Tae Uk LEE, Siheung-si, Gyeonggi-do (KR); Chi Ho YOON, Siheung-si, Gyeonggi-do (KR); Ji Ae PARK, Siheung-si, Gyeonggi-do (KR); Seung Hun CHO, Siheung-si, Gyeonggi-do (KR)

(21) Appl. No.: 19/472,016

(22) PCT Filed: Apr. 2, 2024
(86) PCT No.: PCT/KR2024/004254

§ 371 Date: Oct. 2, 2025

(30) Foreign Application Priority Data
Apr. 4, 2023 (KR) 10-2023-0044122

(51) Int. Cl. B23K 35/02; B23K 1/00; B23K 35/30; B23K 101/40; H10W 72/00; H10W 72/30

(52) U.S. Cl. CPC B23K 35/0244; B23K 1/0016; B23K 35/3006; H10W 72/07336; H10W 72/352; B23K 2101/40

(57) ABSTRACT

The present invention relates to a bonding composition for low-temperature sintering, which employs a silver powder coated with organic silver. A bonding composition for low-temperature sintering according to an aspect of the present invention allows for the provision of a novel type of silver paste composition for low-temperature bonding, an adhesive layer manufactured using same, and a power semiconductor having the adhesive layer, wherein silver particles coated with organic silver is applied in a state of a composition containing a reducing agent and bonded by heating and pressurization, so that the organic silver component on the surface of the silver particles is both reduced and melted to promote the melting of the silver adhesive layer on the whole, whereby the silver adhesive layer can be melted at a relatively low temperature thus enabling a semiconductor to be bonded on a substrate.

### TECHNICAL FIELD

The present invention relates to a bonding composition for low-temperature sintering. More particularly, the present invention relates to a bonding composition for low-temperature sintering, which employs silver powder coated with organic silver.

### BACKGROUND ART

As eco-friendly electric vehicles and the renewable energy market are growing, demand for high-power and high-efficiency power semiconductors is on the rise. Accordingly, the need for wide band gap (WBG) compound semiconductors based on silicon carbide (Sic), gallium nitride (GaN), and the like is growing.

The power semiconductor device as such should support higher power density and switching frequency, and also secure reliability of high-performance electronic modules, and when sinter bonding is performed using conventional lead (Pb)-free solder, there are limitation in achieving these goals, such as damage to semiconductor devices due to bonding at an excessively high temperature.

In order to solve the problems, studies of bonding using a conductive particle-based paste have been attempted, but since the conductive particle-based paste includes an organic binder, residual carbon occurs after sintering, and electrode spread sometimes occurs due to the flowability of the organic binder during sintering. In particular, when the spread and residual carbon occur during sintering at 350 °C or lower, interference with surrounding patterns is caused, or migration occurs when power is applied to cause a reliability problem.

Therefore, there is a demand for an adhesive which has excellent adhesion to a heterojunction device such as a power semiconductor for an electric vehicle without using an organic binder and is sinterable at a low temperature.

### DISCLOSURE

### Technical Problem

The present inventors have technical objects in solving the problems of the prior art.

An object of the present invention is to provide a bonding composition for low-temperature sintering which allows adhesion at a lower adhesion temperature than a conventional adhesive using lead-free solder and silver particles, is melted even at a low temperature and under low pressure and has high adhesive strength, has no void on an adhesive surface, and may implement excellent thermal conductivity and low coefficient of thermal expansion to secure reliability (high durability) of an electronic module.

Another object of the present invention is to provide a bonding composition for low-temperature sintering which may not include an organic binder such as an epoxy resin and an acryl resin to minimize residual carbon during sintering, produce substantially no carbides, and improve an electrode spreading phenomenon.

Still another object of the present invention is to provide a bonding composition for low-temperature sintering for a power semiconductor which may be applied to stencil, screen printing, or the like, and increases an adhesion force to a substrate after bonding a semiconductor by heating after printing and prevents an adhesive surface from being released even when the substrate is dropped at the acceleration of gravity from a height of 2 meters or more or slammed on the floor with the force of a normal adult male.

### Technical Solution

In order to achieve the objects, a study was conducted to develop an adhesive composition which does not produce carbides during sintering by not using a polymer binder, and also, a study was conducted to develop an adhesive composition which allows low-temperature sintering so as to be applied to a power semiconductor and the like and has excellent adhesive strength even with the low-temperature sintering.

As a result, it was found that the objects were achieved by manufacturing a silver paste composition by coating a surface of the silver particle with organic silver which is a silver precursor compound and mixing the particles with a reducing agent and a solvent, and thus, the present invention was completed.

Specifically, in a process of applying the composition to an object to be bonded and then drying the solvent, organic silver is reduced by the reducing agent and silver nanoparticles are formed on the surface of the silver particles, so that a silver adhesive layer formed by the silver particles coming into contact with each other is formed even at a low firing temperature. Though it is not clear, it was found that the reduced silver nanoparticles on the surface of the silver particles promote melting of the silver adhesive layer to provide a new type of silver paste composition for low-temperature adhesion which may be bonded at a relatively low melting temperature, 310 °C or lower, preferably 300 °C or lower.

In one general aspect, a bonding composition for low-temperature sintering includes: surface-coated silver particles in which a surface of the silver particle is coated with a silver precursor compound; and a reducing agent.

As an exemplary embodiment, the bonding composition for low-temperature sintering may be sintered at 310 °C or lower and may have an adhesive strength of 50 MPa or more after the sintering.

As an exemplary embodiment, the bonding composition for low-temperature sintering may not include an organic binder.

As an exemplary embodiment, the silver particles may be agglomerated powder having an average particle diameter of 0.5 to 2 μm and have a primary particle diameter of 45 to 500 nm.

As an exemplary embodiment, the silver precursor compound may be any one or a mixture of two or more selected from the group consisting of silver maleate, silver fumarate, silver glyoxylate, silver pyruvate, silver succinate, silver glutalate, silver gluconate, silver picrate, silver citrate, silver iminodiacetate, silver nitrilotriacetate, silver ethylenediaminetetraacetate, silver benzoate, silver neodecanoate, silver laurate, silver stearate, silver oleate, silver linolate, silver abietate, silver alkylammonium carbamates, silver alkylammonium carbonates, and the like, but is not limited thereto.

As an exemplary embodiment, the reducing agent may be any one or a mixture of two or more selected from the group consisting of methylamine, ethylamine, propylamine, butylamine, pentylamine, aniline, 1,4-phenyldiamine, 4-bromoaniline, 3-amino-1-propanol, alkanolamine, hydrogen peroxide, formic acid, ammonium formate, sodium formate, glyoxal, hydroquinone, hydrazine, pyrogallol, grape sugar, gallic acid, formalin, anhydrous sodium sulfite, sodium sulfoxylate (rongalit), formaldehyde, amine compounds, glycol compounds, glycerol, dimethylformamide, tannic acid, citrate, glucose, ascorbic acid, L(+)-ascorbic acid, isoascorbic acid, ascorbic acid derivatives, oxalic acid, formic acid, ethylene glycol, propylene glycol, polyethylene glycol, diethylene glycol, triethylene glycol, 1,2-propanediol, 1,3-propanediol, 1,2-butanediol, 1,3-butanediol, 1,4-butanediol, 2-butene-1,4-diol, 2,3-butanediol, pentanediol, hexanediol, octanediol, decanol, glycerol, 1,1,1-trihydroxymethylethane, 2-ethyl-2-hydroxymethyl-1,3-propanediol, 1,2,6-hexanetriol, 1,2,3-hexanetriol, 1,2,4-butanetriol, threitol, erythritol, pentaerythritol, phenoxyethanol, hexitol, iminodiethanol, and the like, but is not limited thereto.

In another general aspect, a method for manufacturing a power semiconductor includes:
applying the bonding composition for low-temperature sintering according to the above embodiment on a power semiconductor substrate, and drying the composition, so that reduced silver nanoparticles are formed on a surface of silver particles, thereby forming an adhesive coated layer having a silver adhesive layer formed by the silver particles and the silver nanoparticles coming into contact with each other; and
stacking semiconductor chips on the adhesive coated layer, and performing sintering to form an adhesive layer.

As an exemplary embodiment, the silver nanoparticles may also be formed on the substrate to contribute to adhesion between the substrate and the silver particles.

As an exemplary embodiment, the sintering may be performed at 310 °C or lower.

As an exemplary embodiment, the silver particles may be melted and bonded by the sintering.

As an exemplary embodiment, the reduction may be performed by heating.

As an exemplary embodiment, the heating may be performed at 200 °C or lower.

As an exemplary embodiment, pressurization may be performed at a pressure of 20 MPa or less simultaneously with the sintering.

As an exemplary embodiment, an adhesive strength of the adhesive layer may be 50 MPa or more.

### Advantageous Effects

The bonding composition for low-temperature sintering according to an exemplary embodiment of the present invention may provide a new type of silver paste composition for low-temperature sintering which promotes melting of a silver adhesive layer when organic silver applied on the surface of silver particles is reduced and is melted at a relatively low melting temperature, 310 °C or lower, 250 °C or lower, 230 °C or lower, 210 °C or lower, 200 °C or lower, 180 °C or lower, for example 180 to 310 °C to allow adhesion of a semiconductor on a substrate, an adhesive layer manufactured using the composition, and a power semiconductor having the adhesive layer.

That is, it is considered that when organic silver coated on the surface of silver particles is reduced, silver nanoparticles are formed, and also the reduced silver nanoparticles promote melting of the silver particles which are a base material forming the core. That is, since the silver particles produced by reduction of an organic source coated on the surface promote sintering of silver powder which is a base material in a sintering step during pressurization and heating and serve as a sintering aid, the sintering temperature of the silver powder which is a base material may be lowered, and thus, a bonding composition allowing low-temperature sintering may be provided.

In addition, by using silver powder coated with organic silver, the organic silver serves as a binder which replaces an organic binder such as ethyl cellulose and an acryl resin, which is commonly used when preparing a paste at room temperature or when printing such as stencil or screen printing, and a bonding composition in which when a drying step is ended after the printing, an adhesion force to a substrate is increased and even when the substrate is dropped at the acceleration of gravity from a height of 2 meters or more or slammed on the floor with the force of a normal adult male, the electrode is not released, may be provided.

In addition, since there is no organic binder during sintering, residual carbon may be minimized after the sintering, and electrode spreading due to the flowability of the organic binder during the sintering may be minimized.

In addition, a bonding composition and an electrode formed therefrom do not spread in printing step, drying step, and firing step, or an electrode which does not cause surface diffusion in each step may be formed, using solvents having an obtuse contact angle with a substrate without impairing wettability with silver powder.

The bonding composition for low-temperature sintering according to an embodiment of the present invention may be applied to bonding of electronic devices required in the fields such as power semiconductors for electronic vehicles, aerospace, wind power, space exploration, and deep oil and gas exploration. In addition, the present invention may be applied to a substrate such as high-power LED bonding materials and polyethylene terephthalate films, may be fired at 310 °C or lower, specifically at 200 to 300 °C in the air, and may be applied to a low-resistance sintered body. In addition, during the sintering, bonding may be performed with melting which is sufficiently performed even under no pressure or a pressure of 20 MPa or less, 15 MPa or less, preferably 10 MPa.

### DESCRIPTION OF DRAWINGS

FIG. 1 is a cross-sectional view showing an embodiment of a surface-coated silver particle of the present invention.

10: Silver particle
20: Silver precursor compound coating layer
100: Surface coated silver particle

### BEST MODE

Hereinafter, the present invention will be described in more detail. However, the following specific examples or exemplary embodiments are only a reference for describing the present invention in detail, and the present invention is not limited thereto, and may be implemented in various forms.

In addition, unless otherwise defined, all technical terms and scientific terms have the same meanings as those commonly understood by one of those skilled in the art to which the present invention pertains. The terms used herein are only for effectively describing a certain specific example and are not intended to limit the present invention.

In addition, the singular form used in the specification and claims appended thereto may be intended to include a plural form also, unless otherwise indicated in the context.

In addition, unless particularly described to the contrary, “comprising” any elements will be understood to imply further inclusion of other elements rather than the exclusion of other elements.

In addition, unless particularly defined in the present invention, when a layer or member is positioned “on” another layer or member, not only is the layer or member in contact with another layer or member, but also another layer or member exists between two layers or two members.

In addition, when unique manufacture and material allowable errors are suggested in the mentioned meaning, the terms such as “about” and “substantially” used in the present specification are used in the meaning of the numerical value or in the meaning close to the numerical value, and are used for preventing the disclosure mentioning a correct or absolute numerical value for better understanding of the present invention from being unfairly used by an unconscionable infringer.

An embodiment of the present invention provides a bonding composition for low-temperature sintering, that is, a silver paste composition for low-temperature sintering including surface-coated silver particles in which a surface of the silver particle is coated with a silver precursor (also referred to as “organic silver”) compound; and a reducing agent.

Another embodiment of the present invention provides a bonding composition for low-temperature sintering, that is, a silver paste composition for low-temperature sintering including surface-coated silver particles in which a surface of the silver particle is coated with a silver precursor (also referred to as “organic silver”) compound; a reducing agent; and a solvent.

As an exemplary embodiment, the silver particles are not limited as long as they are commonly used in the art, and their shape such as spherical and flake shapes are also not limited. In addition, the silver particles may be manufactured by a common manufacturing method such as a wet method and a dry method.

The silver particles may be primary particles, or secondary particles formed by agglomeration of the primary particles, and though they are not limited, they may be agglomerated powder having an average particle diameter of 0.5 to 2 μm and may have a primary particle diameter of 45 to 500 nm. It is advantageous to express low-temperature sintering and adhesive strength within the range, which is thus preferred, but is not limited thereto. In addition, though the shape of the silver particles is not limited, it may be, for example, spherical, flake, or agglomerated shape, or the like, the silver particles may be a mixture of silver particles having one or more shapes, and a plurality of silver particles including agglomerated secondary particles may be used.

As an exemplary embodiment, any silver precursor compound may be used without limitation as long as it is a material which is coated on the surface of the silver particle and then reduced to a silver metal by a reducing agent in a process of heating for drying the solvent of the bonding composition.

The silver precursor compound may be organic silver, and the use of the organic silver may contribute to expression of low-temperature sintering and adhesive strength of an adhesive layer without using a separate polymer binder.

An exemplary embodiment of the organic silver may be, specifically, for example, any one or a mixture of two or more selected from the group consisting of silver maleate, silver fumarate, silver glyoxylate, silver pyruvate, silver succinate, silver glutalate, silver gluconate, silver picrate, silver citrate, silver iminodiacetate, silver nitrilotriacetate, silver ethylenediaminetetraacetate, silver benzoate, silver neodecanoate, silver laurate, silver stearate, silver oleate, silver linolate, silver abietate, silver alkylammonium carbamates, silver alkylammonium carbonates, and the like, but is not limited thereto.

More preferably, it may be silver neodecanoate, silver laurate, silver stearate, silver oleate, silver linolate, and the like, and since dispersion stability is good, reactivity with the reducing agent at a drying temperature of the solvent is good, and long-term storage stability in the solvent of the bonding composition is excellent by using the organic silver, which is thus preferred, but the present invention is not limited thereto.

The silver precursor compound may be coated at a thickness of 1 nm to 60 nm on the surface of the silver particle, and within the range, long-term storage stability is excellent and adhesive strength is excellent, which is thus preferred, but the present invention is not limited thereto. Whether it is coated may be checked using GC-MS.

A content of the silver precursor may be 0.01 to 10.0 parts by weight, 0.05 to 5.0 parts by weight, 0.1 to 3.0 parts by weight, or 0.5 to 2.0 parts by weight, with respect to 100 parts by weight of the surface-coated silver particles, but is not limited thereto.

As an exemplary embodiment, a method for manufacturing the surface-coated silver particles may be adding silver particles to a solution in which a silver precursor compound is dispersed to coat the silver particles with the compound through drying, or dispersing the silver particles in a solvent, adding a solution including silver ions in that state, and mixing a fatty acid and a pH regulator therewith to synthesize a silver precursor compound and coat the surface of the silver particle. The silver precursor compound solution may be an aqueous dispersion including a silver precursor compound.

As another method, the silver precursor compound may be physically mixed with silver particles to obtain surface-treated silver particles. An example of the mixing device may include a planetary mixer, a tumbler mixer, a Henschel mixer, an intensive mixer, and the like, and also, is not particularly limited as long as the device may physically adsorb the silver precursor compound on the surface of the silver particle. In order to adsorb a solid silver precursor compound, it is advantageous for all particles to be evenly treated by liquefaction, but since the silver precursor is reduced during the liquefaction and may be precipitated as silver particles, the silver precursor may be adsorbed on the surface using a surface treatment device in a wax-like state without liquefaction. Additionally, a method for adsorbing the silver precursor on the surface of the particles, excluding the characteristic process, may be appropriately adopted.

As an exemplary embodiment, any reducing agent may be used without limitation as long as it is a material which reduces the silver precursor compound by heating in a process of applying the composition and drying to manufacture a thin film.

Specifically, an example of the reducing agent may be any one or a mixture of two or more selected from the group consisting of methylamine, ethylamine, propylamine, butylamine, pentylamine, aniline, 1,4-phenyldiamine, 4-bromoaniline, 3-amino-1-propanol, alkanolamine, hydrogen peroxide, formic acid, ammonium formate, sodium formate, glyoxal, hydroquinone, hydrazine, pyrogallol, grape sugar, gallic acid, formalin, anhydrous sodium sulfite, sodium sulfoxylate (rongalit), formaldehyde, amine compounds, glycol compounds, glycerol, dimethylformamide, tannic acid, citrate, glucose, ascorbic acid, L(+)-ascorbic acid, isoascorbic acid, ascorbic acid derivatives, oxalic acid, formic acid, ethylene glycol, propylene glycol, polyethylene glycol, diethylene glycol, triethylene glycol, 1,2-propanediol, 1,3-propanediol, 1,2-butanediol, 1,3-butanediol, 1,4-butanediol, 2-butene-1,4-diol, 2,3-butanediol, pentanediol, hexanediol, octanediol, decanol, glycerol, 1,1,1-trihydroxymethylethane, 2-ethyl-2-hydroxymethyl-1,3-propanediol, 1,2,6-hexanetriol, 1,2,3-hexanetriol, 1,2,4-butanetriol, threitol, erythritol, pentaerythritol, phenoxyethanol, hexitol, iminodiethanol, and the like, but is not limited thereto.

Specifically, the reducing agent may be an alcohol-based compound selected from decanol, ethylene glycol, propylene glycol, 1,3-propanediol, diethylene glycol, triethylene glycol, and the like.

It is preferred that the reducing agent is used at 1 part by weight or more with respect to 100 parts by weight of the silver particles in terms of the yield of precipitated silver powder, and when a reducing agent having a relatively weak reducing power like the alcohol-based compound is used, it is preferred that the amount of the reducing agent used is increased. For example, the content of the reducing agent may be adjusted depending on the used type, and specifically, for example, when the alcohol-based compound is used as a reducing agent, it may be used at 2 parts by weight to 100 parts by weight, 10 to 70 parts by weight, or 20 to 60 parts by weight, with respect to 100 parts by weight of the silver particles.

In addition, it may be advantageous during drying to include a solvent having a boiling point of 100 to 200 °C as the reducing agent, and the content may be 10 to 50 parts by weight.

As an exemplary embodiment, the bonding composition for low-temperature sintering of the present invention may use an alcohol-based compound, for example, decanol, ethylene glycol, propylene glycol, 1,3-propanediol, diethylene glycol, triethylene glycol, and the like, as the reducing agent, and when the alcohol-based compound is used as the reducing agent, a separate solvent may not be required. However, if necessary, a separate solvent may be further added in order to further improve applicability and dryness. In addition, when other materials are used without using the alcohol-based compound as the reducing agent, the alcohol-based solvent may be used as the solvent.

As an exemplary embodiment, any solvent may be used without limitation as long as it is a solvent which has excellent wettability with silver particles, has an obtuse contact angle with a substrate, and may form an electrode which does not undergoes spreading of an electrode paste in composition application, drying and sintering steps, or surface diffusion in each step. Specifically, a solvent having a boiling point of 100 to 290 °C may be used without limitation.

The type of solvent is not limited as long as it is a solvent having a boiling point of 100 to 290 °C. Specifically, for example, any one or two or more solvents selected from the group consisting of ether-based solvents such as ethylene glycol monoethyl ether, ethylene glycol monobutyl ether, diethylene glycol monomethyl ether, diethylene glycol monoethyl ether, diethylene glycol monobutyl ether, propylene glycol monomethyl ether, propylene glycol monoethyl ether, propylene glycol monobutyl ether, dipropylene glycol monomethyl ether, dipropylene glycol monoethyl ether, dipropylene glycol monobutyl ether, diethylene glycol dimethyl ether, and dipropylene glycol dimethyl ether; terpene-based solvents such as terpineol, terpineolacetate, dihydroterpineol, and dihydroterpinylacetate; alcohol-based solvents such as ethylene glycol, propylene glycol, polyethylene glycol, diethylene glycol, triethylene glycol, 1,2-propanediol, 1,3-propanediol, 1,2-butanediol, 1,3-butanediol, 1,4-butanediol, 2-butene-1,4-diol, 2,3-butanediol, pentanediol, hexanediol, octanediol, decanol, glycerol, 1,1,1-trihydroxymethylethane, 2-ethyl-2-hydroxymethyl-1,3-propanediol, 1,2,6-hexanetriol, 1, 2, 3-hexanetriol, 1,2,4-butanetriol, threitol, erythritol, pentaerythritol, phenoxyethanol, hexitol, and iminodiethanol may be used, but the present invention is not limited thereto. As an exemplary embodiment, the bonding composition for low-temperature sintering may have a solid content of 30 to 90 wt % and a viscosity of 30 Pa·s to 150 Pa·s (Brookfield, DVII, SCR 14 spindle @ 25 °C, 10 rpm), and within the range, stencil and screen printing may be performed to allow mass production, which is thus preferred, but the present invention is not limited thereto.

Another embodiment of the present invention provides a method for manufacturing a power semiconductor without using an organic binder, including: applying the bonding composition for low-temperature sintering according to the above embodiment on a power semiconductor substrate, and drying the composition, so that reduced silver nanoparticles are formed on a surface of silver particles, thereby forming an adhesive coated layer having a silver adhesive layer formed by the silver particles and the silver nanoparticles coming into contact with each other; and

stacking semiconductor chips on the adhesive coated layer and then performing sintering to form an adhesive layer.

Since the bonding composition for low-temperature sintering used in the manufacturing method is as described above, overlapping description will be omitted.

As an exemplary embodiment, the step of applying the bonding composition for low-temperature sintering on a power semiconductor substrate may be performed using a roller, a brush, spray application, and the like, without limitation, and stencil or screen printing may be performed.

As an exemplary embodiment, it is preferred that the drying is performed at a temperature at which rearrangement of silver particles occurs with the drying of the solvent used in the bonding composition for low-temperature sintering and simultaneously the reducing agent reacts with the silver precursor compound to perform reduction. That is, the reduction may be performed by heating at the drying temperature. Specifically, the heating may be performed at 70 °C or higher or at 70 to 200 °C. Otherwise, it may be performed at 100 to 150 °C.

As the reduction is performed by the drying, the silver particles and the silver nanoparticles come into contact with each other by the silver nanoparticles produced by reduction on the surface of the silver particle, thereby forming a silver adhesive layer.

As an exemplary embodiment, the silver particles may be melted by the sintering and bonded. The sintering may be performed at a temperature at which the silver particles are sintered, and according to the manufacturing method of the present invention, sintering of silver powder is promoted in the sintering step by the silver nanoparticles formed on the surface of the silver particle and between the substrate and the silver particles by the reduction, thereby lowering the sintering temperature as compared with the original sintering temperature of the silver powder. In addition, since a separate polymer binder is not used, carbides do not occur.

Specifically, for example, the sintering may be performed at 310 °C or lower, more specifically 300 °C or lower, 250 °C or lower, 230 °C or lower, 200 °C or lower, 180 °C or lower, for example, 180 to 310 °C. In addition, during the sintering, adhesion may be performed by sufficiently melting under no pressure or with a pressure of 20 MPa or less, 15 MPa or less, preferably 10 MPa or less.

The adhesive layer manufactured according to an embodiment of the present invention has excellent adhesive strength and may provide an effect of not releasing an electrode even when it is dropped at the acceleration of gravity from a height of 2 meters or more or slammed on the floor with the force of a normal adult male. More specifically, the adhesive strength may be 50 MPa or more or 50 to 150 MPa, but is not limited thereto.

Hereinafter, the present invention will be described in more detail with reference to the examples and the comparative examples. However, the following examples and comparative examples are only an example for describing the present disclosure in more detail, and do not limit the present disclosure in any way.

Hereinafter, the physical properties were evaluated as follows:

### 1) Applicability

The bonding compositions manufactured in the examples and the comparative examples were printed on a metal stencil mask to apply the compositions on 10 patterns of 0.6×0.6 mm, 10 patterns of 1.0×1.0 mm, 10 patterns of 3.0×3.0 mm, and 10 patterns of 5.0×5.0 mm on a silver-plated copper substrate at a printed thickness of 200 μm, and then the number of printing defects occurring was evaluated.

When 2 or less defects occurred, it was indicated as excellent, and when more than 3 defects occurred, it was indicated as poor.

### 2) Dry Adhesion Force

The bonding compositions manufactured in the examples and the comparative examples were applied on a silver-plated copper substrate at a printed thickness of 200 μm identically to the above applicability evaluation, the substrate was dried with hot air at 130 °C for 30 minutes, and then dropped from a height of 1 m, and then the number of damaged or dropped patters was evaluated.

Herein, a partially dropped state in each pattern was regarded as being dropped. As the evaluation criterion, when the number of patterns with no damage was 39 to 40, it was evaluated as excellent adhesiveness (PASS) and when the number was less than that, it was evaluated as poor adhesiveness (NG).

### 3) Sinterability

The bonding compositions manufactured in the examples and the comparative examples were applied on a silver-plated copper substrate with 6 patterns having a size of 2.8×2.8 mm and then dried with hot air at 130 °C for 30 minutes to obtain electrode patterns. A silver-plated copper block of 3×3×2 mm was placed on the applied and dried electrode pattern and sintered by heating from room temperature to an actually measured temperature of 310 °C (set temperature: 300 °C) at a heating rate of 95 °C/min for about 180 seconds while pressurizing to 10 MPa. Sinterability was determined by observing a sintered surface with a field emission scanning electron microscope (FE-SEM), and when a porosity was 19% or less, it was determined to be very excellent, when a porosity was 25% or less, it was determined to be excellent, and when a porosity was 30% or less, it was determined to be good.

### 4) Adhesive Strength

After performing sintering identically to the above sinterability evaluation of 3), adhesive strength was measured.

The adhesive strength of the adhesive layer was measured as a Die Shear value according to AMIL-STD-883 method No. 2019 die shear strength using equipment of DAGE4000 DS200 Kg.

As the evaluation criterion, when the adhesive strength was 60 MPa or more, it was evaluated as very excellent, when 50 MPa or more, it was evaluated as good (PASS), and when less than 50 MPa, it was evaluated as poor (NG).

### 5) BLT Evaluation

Sintering was performed identically to the sinterability evaluation of 3), and then bonded line thickness (BLT, μm) was measured.

The measurement of BLT was performed by measuring a BLT thickness through SEM observation of a fracture surface of a sintered sample. As the evaluation criterion, when BLT was 50 μm or less, it was evaluated as good (PASS), and when BLT was more than that, it was evaluated as poor (NG).

### 6) Presence or Absence of Residual Carbon

Heating from room temperature (about 25 °C) to 600 °C was performed at a heating rate of 10 °C/min, using a themogravimetric differential thermoanalyzer (TA Instruments Ltd., model name: SDT Q600), thereby measuring a weight loss depending on the temperature of the composition. The complete evaporation of the solvent and the decomposition of the metal-organic precursor were shown at 250 °C or lower. Furthermore, since the exothermic peak of differential thermal analysis occurred at 250 °C or lower, it was confirmed that most of the organic material was completely oxidized at 250 °C or lower. For the total weight loss at 250 °C, when heating, in a metallic gel at 250 °C, the organic part was completely separated from a silver element and evaporated to leave only bulk silver metal without leaving carbon residues. Therefore, the pyrolysis of the silver precursor deposited only pure silver metal without carbon residues. A residual percentage at TGA at a temperature of 250 °C or higher was close to a theoretical silver weight percentage of silver particles. This clearly shows that the pyrolysis of particles completely occurred. The value of the residual carbon content of each sintered sample was measured with a CS analyzer (LECO, model name: CS744), and the values were relatively compared based on the value of Example 1.

### Example 1

1) Manufacture of Silver Particles Coated with Organic Silver

Silver particles which were agglomerated powder having an average particle diameter of 1.7 μm and had an average particle diameter of primary silver particles of 70 nm were used.

The silver particles were added to an intensive mixer, 0.5 parts by weight of silver laurate as organic silver with respect to 100 parts by weight of the silver particles was sequentially added, and stirring was performed at 1500 rpm for 180 minutes to manufacture coated silver particles (referred to as “organic silver coated silver particle (1)” in the following Table 1).

### 2) Manufacture of Silver Paste Composition

10 parts by weight of propylene glycol and 30 parts by weight of 1,3-propanediol as a reducing agent, and 30 parts by weight of terpineol were mixed with respect to 100 parts by weight of the surface-coated silver particles manufactured above to manufacture a bonding composition for low-temperature sintering. The physical properties of the bonding composition for low-temperature sintering were evaluated and are shown in Tables 1 and 2.

### 3) Manufacture and Evaluation of Power Semiconductor Sintered Sample

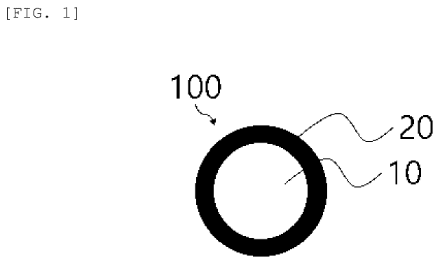

The bonding composition for low-temperature sintering manufactured above was applied with 8 patterns on a silver-plated copper (DBC) substrate, dried with hot air at 130 °C for 30 minutes, 3×3 mm copper blocks (silver-plated copper) were placed on the printed and dried electrode patterns, respectively, and pressurizing firing was performed at 310 °C while pressurizing at 10 MPa. The adhesive strength of each sample after pressurizing firing was measured, and an average of values excluding the maximum and minimum values was set as an adhesive strength value of each sample. As a result, the adhesive strength was 63.9 MPa, which was confirmed to be very excellent. The evaluation results are shown in FIG. 1.

### Example 2

The process was performed in the same manner as in Example 1, except that the content of the reducing agent was changed as shown in the following Table 1. The evaluation results are shown in FIG. 1.

### Example 3

The process was performed in the same manner as in Example 2, except that the coated silver particles were changed.

Silver particles (referred to as “organic silver coated silver particle (2)”) which were surface-coated in the same manner as in Example 1 were manufactured except that the content of silver laurate as organic silver was changed to 2 parts by weight. The evaluation results are shown in FIG. 1.

### Comparative Example 1

Silver particles which were agglomerated powder having an average particle diameter of 200 nm, formed by agglomeration of silver particles having a primary particle diameter of 45 nm were used without using surface-coated silver particles of Example 1. That is, silver particles having an average particle diameter of 200 nm which were not surface-coated (referred to as “uncoated silver particle (3) in the following Table 1) were mixed with the reducing agent and the solvent at the content shown in Table 1 to manufacture a composition. The prepared composition was applied on a power semiconductor substrate and dried with hot air at 130 °C, 3×3 mm copper blocks were placed on the printed and dried electrode patterns, respectively, and pressurizing sintering was performed at 310 °C while pressurizing at 10 MPa. The adhesive strength of each of the evaluated samples was measured, and an average of values excluding the maximum and minimum values was set as an adhesive strength value of each sample. As a result, it was confirmed that the adhesive strength was 49.2 MPa, which was lower than that of Example 1. In addition, it was confirmed that sintering was performed at a high temperature which was a sintering temperature of 300 °C or higher. The evaluation results are shown in FIG. 1.

### Comparative Example 2

Surface-coated silver particles were manufactured in the same manner as in Example 1, except that particles coated with a fatty acid were used as the surface-coated silver particles, as described later.

In addition, a bonding composition for low-temperature sintering was manufactured in the same manner as in Example 1, using the manufactured surface-coated silver particles, thereby forming an adhesive layer on a power semiconductor. As a result, it was confirmed that the adhesive strength was 10.2 MPa, which was lower than that of Example 1. Even more, one of six adherends was released from the substrate.

Silver particles which were agglomerated powder having a primary particle diameter of 45 nm and an average particle diameter of 200 nm were used.

0.5 parts by weight of lauric acid as a fatty acid with respect to 100 parts by weight of the silver particles and the silver particles were weighed and sequentially added to an intensive mixer, and stirring was performed at 1500 rpm for 180 minutes to manufacture coated silver particles (referred to as “fatty acid-coated silver particle (4)” in the following Table 1). The evaluation results are shown in FIG. 1.

### Comparative Example 3

A composition was manufactured in the same manner as in Example 1, except that a binder resin was further included.

A bonding composition for low-temperature sintering was manufactured, using the same surface-coated silver particles as in Example 1, by mixing 10 parts by weight of propylene glycol and 30 parts by weight of 1,3-propanediol as a reducing agent, 30 parts by weight of terpineol as a solvent, and 0.4 parts by weight of ethyl cellulose resin (DOW, ETHOCEL STD 4) as a binder resin with respect to 100 parts by weight of the organic silver-coated silver particle (1). When the manufactured bonding composition for low-temperature sintering was applied on a power semiconductor substrate, the applied material was dragged in.

As a result of performance evaluation in the same manner as in Example 1, the adhesive strength was 50.3 MPa, which was good, but lower than that of Example 1. Considering that as a result of measurement with a differential gravimetric analyzer, a DT exothermic peak was expressed at higher than 250 °C and a carbon content was detected at 206 ppm, it was evaluated that a carbide as residual carbon remained even after sintering to interfere with the interfacial bonding force of silver. The evaluation results are shown in FIG. 1.

### Comparative Example 4

A silver precursor and a reducing agent were mixed and used in the composition, without using the surface-modified silver particles.

Silver particles which were agglomerated powder having an average particle diameter of 200 nm, formed by agglomeration of silver particles having a primary particle diameter of 45 nm, were used. That is, 0.5 parts by weight of silver laurate as organic silver with respect to 100 parts by weight of silver particles having an average particle diameter of 200 nm which were not surface-coated (referred to as “uncoated silver particle (3) in the following Table 1) were mixed with the reducing agent and the solvent at the content shown in the following Table 1, thereby manufacturing a bonding composition for low-temperature sintering.

The bonding composition for low-temperature sintering manufactured above was applied on a power semiconductor substrate, dried with hot air at 130 °C for 30 minutes, 3×3 mm copper blocks (silver-plated copper) were placed on the printed and dried electrode patterns, respectively, and pressurizing firing was performed at 310 °C while pressurizing at 10 MPa. The adhesive strength of each of the evaluated samples was measured, and an average of values excluding the maximum and minimum values was set as an adhesive strength value of each sample.

As a result, it was confirmed that the adhesive strength was 38.4 MPa, which was lower than that of Example 1. In addition, when the organic silver was mixed with the composition and application was performed, it was found that wettability was low, and sintering adhesiveness was low, as compared with the case of using the coated particles as in the present invention. The evaluation results are shown in FIG. 1.

TABLE 1

| | | | | Comparative | Comparative | Comparative | Comparative |
|---|---|---|---|---|---|---|---|
| | Example 1 | Example 2 | Example 3 | Example 1 | Example 2 | Example 3 | Example 4 |
| Type/content | Organic | Organic | Organic | Uncoated | Fatty acid | Organic | Uncoated |
| (part by | silver | silver | silver | silver | coated | silver | silver |
| weight) of | coated | coated | coated | particle | silver | coated | particle |
| silver | silver | silver | silver | (3)/100 | particle | silver | (3)/100 |
| particle | particle | particle | particle | | (4)/100 | particle | |
| | (1)/100 | (1)/100 | (2)/100 | | | (1)/100 | |
| Propylene | 10 | 20 | 20 | 10 | 10 | 10 | 10 |
| glycol (part | | | | | | | |
| by weight) | | | | | | | |
| 1,3- | 30 | 20 | 20 | 30 | 30 | 30 | 30 |
| propanediol | | | | | | | |
| (part by | | | | | | | |
| weight) | | | | | | | |
| Terpineol | 30 | 30 | 30 | 30 | 30 | 30 | 30 |
| (part by | | | | | | | |
| weight) | | | | | | | |
| Binder (part | — | — | — | — | — | 0.4 | — |
| by weight) | | | | | | | |
| Organic | — | — | — | — | — | — | 0.5 |
| silver (part | | | | | | | |
| by weight) | | | | | | | |
| Applicability | Excellent | Excellent | Excellent | Poor | Poor | Poor | Excellent |
| Dry adhesion | Excellent | Excellent | Excellent | Poor | Poor | Good | Excellent |
| force | | | | | | | |
| Sinterability | Very | Very | Very | Good | Poor | Poor | Excellent |
| | excellent | excellent | excellent | | | | |
| Adhesive | Very | Excellent | Excellent | Excellent | Poor | Excellent | Poor |
| strength | excellent | | | | | | |
| Residual | 0 | 0 | 0 | 256 | 0 | 206 | 193 |
| carbon (ppm) | | | | | | | |
| BLT | Good | Good | Good | Good | Poor | Poor | Good |
| | (48.7 μm) | (48.7 μm) | (48.3 μm) | (48.7 μm) | (60.4 μm) | (50.4 μm) | (46.4 μm) |

Hereinabove, although the present invention has been described by specified matters exemplary and specific embodiments, they have been provided only for assisting in the entire understanding of the present invention, and the present invention is not limited to the exemplary embodiments. Various modifications and changes may be made by those skilled in the art to which the present invention pertains from the description.

Therefore, the spirit of the present invention should not be limited to the above-described exemplary embodiments, and the following claims as well as all modifications equal or equivalent to the claims are intended to fall within the scope and spirit of the invention.

1. A bonding composition for low-temperature sintering comprising: surface-coated silver particles in which a surface of the silver particle is coated with a silver precursor compound; and a reducing agent.

2. The bonding composition for low-temperature sintering of claim 1, wherein the bonding composition for low-temperature sintering is sintered at 310 °C or lower and has an adhesive strength of 50 MPa or more after the sintering.

3. The bonding composition for low-temperature sintering of claim 1, wherein the bonding composition for low-temperature sintering does not include an organic binder.

4. The bonding composition for low-temperature sintering of claim 1, wherein the silver particles include agglomerated powder having an average particle diameter of 0.5 to 2 μm and have a primary particle diameter of 45 to 500 nm.

5. The bonding composition for low-temperature sintering of claim 1, wherein the silver precursor compound is any one or a mixture of two or more selected from the group consisting of silver maleate, silver fumarate, silver glyoxylate, silver pyruvate, silver succinate, silver glutalate, silver gluconate, silver picrate, silver citrate, silver iminodiacetate, silver nitrilotriacetate, silver ethylenediaminetetraacetate, silver benzoate, silver neodecanoate, silver laurate, silver stearate, silver oleate, silver linolate, silver abietate, silver alkylammonium carbamates, and silver alkylammonium carbonates.

6. The bonding composition for low-temperature sintering of claim 1, wherein the reducing agent is any one or a mixture of two or more selected from the group consisting of methylamine, ethylamine, propylamine, butylamine, pentylamine, aniline, 1,4-phenyldiamine, 4-bromoaniline, 3-amino-1-propanol, alkanolamine, hydrogen peroxide, formic acid, ammonium formate, sodium formate, glyoxal, hydroquinone, hydrazine, pyrogallol, grape sugar, gallic acid, formalin, anhydrous sodium sulfite, sodium sulfoxylate (rongalit), formaldehyde, amine compounds, glycol compounds, glycerol, dimethylformamide, tannic acid, citrate, glucose, ascorbic acid, L(+)-ascorbic acid, isoascorbic acid, ascorbic acid derivatives, oxalic acid, formic acid, ethylene glycol, propylene glycol, polyethylene glycol, diethylene glycol, triethylene glycol, 1,2-propanediol, 1,3-propanediol, 1,2-butanediol, 1,3-butanediol, 1,4-butanediol, 2-butene-1,4-diol, 2,3-butanediol, pentanediol, hexanediol, octanediol, decanol, glycerol, 1,1,1-trihydroxymethylethane, 2-ethyl-2-hydroxymethyl-1,3-propanediol, 1,2,6-hexanetriol, 1,2,3-hexanetriol, 1,2,4-butanetriol, threitol, erythritol, pentaerythritol, phenoxyethanol, hexitol, and iminodiethanol.

7. A method for manufacturing a power semiconductor, the method comprising:
applying the bonding composition for low-temperature sintering of claim 1 on a power semiconductor substrate, and drying the composition, so that reduced silver nanoparticles are formed on a surface of silver particles, thereby forming an adhesive coated layer having a silver adhesive layer formed by the silver particles and the silver nanoparticles coming into contact with each other; and
stacking semiconductor chips on the adhesive coated layer, and performing sintering to form an adhesive layer.

8. The method for manufacturing a power semiconductor of claim 7, wherein the silver nanoparticles are also formed on the substrate to contribute to adhesion between the substrate and the silver particles.

9. The method for manufacturing a power semiconductor of claim 7, wherein the sintering is performed at 310 °C or lower.

10. The method for manufacturing a power semiconductor of claim 7, wherein the silver particles are melted by the sintering and bonded.

11. The method for manufacturing a power semiconductor of claim 7, wherein the reduction is performed by heating.

12. The method for manufacturing a power semiconductor of claim 11, wherein the heating is performed at 200 °C or lower.

13. The method for manufacturing a power semiconductor of claim 9, wherein pressurization is simultaneously performed at a pressure of 20 MPa or less during the sintering.

14. The method for manufacturing a power semiconductor of claim 7, wherein the adhesive layer has an adhesive strength of 50 MPa or more.
